(19) United States
(12) Patent Application Publication
(10) Pub. No.: US 2017/0170758 A1
(43) Pub. Date: Jun. 15, 2017

(54) DETERMINING THE PARKED POSITION OF A PERMANENT-MAGNET MOTOR

(71) Applicant: Dyson Technology Limited, Wiltshire (GB)

(72) Inventors: Christopher John BATEMAN, Swindon (GB); Libo ZHENG, Swindon (GB)

(73) Assignee: Dyson Technology Limited, Wiltshire (GB)

(21) Appl. No.: 15/376,304

(22) Filed: Dec. 12, 2016

(30) Foreign Application Priority Data
Dec. 10, 2015 (GB) 1521781.3

(51) Int. Cl. H02P 6/18; H02P 6/20; G01R 31/34; H02P 27/06

(52) U.S. Cl. CPC H02P 6/18; H02P 27/06; H02P 6/20; G01R 31/346

(57) ABSTRACT

A method of determining the parked position of a rotor of a permanent-magnet motor, including applying a first voltage to a phase winding of the motor, measuring a first parameter, removing the first voltage, waiting for current in the phase winding to decrease to zero, applying a second voltage having the opposite polarity, measuring a second parameter, comparing the first parameter and the second parameter, and determining that the rotor is in a first parked position if the first parameter is less than the second parameter, and that the rotor is in a second parked position if the first parameter is greater than the second parameter. The first parameter and the second parameter each correspond to one of (i) the time taken for current in the phase winding to exceed a threshold, and (ii) the magnitude of current in the phase winding at the end of a time interval.

### REFERENCE TO RELATED APPLICATIONS

This application claims the priority of United Kingdom Application No. 1521781.3, filed Dec. 10, 2015, the entire contents of which are incorporated herein by reference.

### FIELD OF THE INVENTION

The present invention relates to a method of determining the parked position of a rotor of a permanent-magnet motor.

### BACKGROUND OF THE INVENTION

In order to start a permanent-magnet motor, it is necessary to know in which position the rotor has parked so that the appropriate polarity of voltage may be applied to the phase windings. The motor may include a Hall-effect sensor for determining the position of the rotor. However, tolerances in the position of the sensor may mean that sensor is unable to determine reliably the parked position of the rotor. As an alternative to a Hall-effect sensor, the motor may employ a sensorless scheme for determining the position of the rotor. However, sensorless schemes typically require the rotor to be moving in order to determine the position of the rotor.

### SUMMARY OF THE INVENTION

The present invention provides a method of determining the parked position of a rotor of a permanent-magnet motor, the method comprising applying a first voltage to a phase winding of the motor; measuring a first parameter corresponding to one of (i) the time taken for current in the phase winding to exceed a threshold, and (ii) the magnitude of current in the phase winding at the end of a time interval; removing the first voltage from the phase winding; waiting for current in the phase winding to decrease to zero; applying a second voltage to the phase winding of the motor, the second voltage having the same magnitude but the opposite polarity to that of the first voltage; measuring a second parameter corresponding to one of (i) the time taken for current in the phase winding to exceed the threshold, and (ii) the magnitude of current in the phase winding at the end of the time interval; comparing the first parameter and the second parameter; and determining that the rotor is in a first parked position if the first parameter is less than the second parameter, and that the rotor is in a second parked position if the first parameter is greater than the second parameter.

When a voltage is applied to the phase winding, a stator field is generated. As the phase current increases, the density of the stator flux increases and eventually begins to saturate. As the stator saturates, the inductance of the phase winding decreases and thus the phase current increases at a faster rate. Depending on the polarity of the applied voltage and the parked position of the rotor, the rotor flux will either align with or oppose the stator flux. When the rotor flux is aligned with the stator flux, saturation occurs more quickly and thus the phase current increases at a faster rate. Conversely, when the rotor flux opposes the stator flux, saturation occurs more slowly and thus the phase current increases at a slower rate. The present invention makes use of this behaviour to determine the parked position of the rotor. In particular, a first voltage is applied to the phase winding and the first parameter is measured. A second voltage is then applied to the phase winding and the second parameter is measured. Since the second voltage has the opposite polarity to the first voltage, the rotor flux will be aligned with the stator flux during one of the two measurements, and the rotor flux will oppose the stator flux during the other of the two measurements. The first parameter will therefore be less than or greater than the second parameter depending on the parked position of the rotor. The present invention is therefore able to determine the parked position of the rotor without the need for a Hall-effect sensor or the like.

Conceivably, the position of the rotor might be determined by measuring just the first parameter and comparing this against a discriminating threshold. For example, the rotor may be determined to be at the first parked position if the first parameter is less than the discriminating threshold, and at the second parked position of the first parameter is greater than the threshold. However, tolerances in the motor as well as changes in the temperature of the rotor will introduce a variance into the measured parameter. As a result, the measured parameter may be less than the discriminating threshold when it should be greater, or vice versa. The method would then incorrectly determine the parked position of the rotor. By measuring and comparing two parameters, the parked position of the rotor may be determined more reliably. In particular, even though there may be a variance associated with each of the two parameters, one of the parameters continues to be less than the other. As a result, the parked position of the rotor may be determined more reliably.

It is not essential that the threshold or the time interval is predetermined or fixed, so long as the same threshold and the same time interval are used when measuring each of the two parameters. So, for example, the method may comprise selecting a threshold or time interval that depends on the magnitude of the applied voltage.

Waiting for current in the phase winding to decrease to zero may comprise waiting a specific period of time sufficient for the current to decrease to zero. This then has the advantage that it is not necessary to measure the phase current after the first voltage has been removed and thus a cheaper current sensor may be employed. Alternatively, waiting for current in the phase winding to decrease to zero may comprise measuring the phase current and then applying the second voltage only when the measured current reaches zero.

The present invention also provides a permanent-magnet motor comprising a rotor, a stator and a control system configured to performed a method as described above.

The control system may comprise an inverter, a gate driver module, a controller, and a current sensor. The inverter is then coupled to the phase winding, and the gate driver module drives the opening and closing of switches of the inverter in response to control signals output by the controller. The current sensor outputs a signal that provides a measure of the current in the phase winding. The controller outputs a first set of control signals such that the first voltage is applied to the phase winding, measures the first parameter using the signal output by the current sensor, outputs a second set of control signals such that the first voltage is removed from the phase winding, outputs a third set of control signals such that the second voltage is applied to the phase winding, measures the second parameter using the signal output by the current sensor, compares the first parameter and the second parameter, and determines the parked position of the rotor in response to the comparison.

In some embodiments, the control system (e.g., a controller of the control system) comprises one or more processors, memory, and one or more programs, wherein the one or more programs are stored in the memory and configured to be executed by the one or more processors, the one or more programs including instructions that when executed by the one or more processors, cause the control system to: apply a first voltage to a phase winding of the motor; measure a first parameter corresponding to one of (i) the time taken for current in the phase winding to exceed a threshold, and (ii) the magnitude of current in the phase winding at the end of a time interval; remove the first voltage from the phase winding; wait for current in the phase winding to decrease to zero; apply a second voltage to the phase winding of the motor, the second voltage having the same magnitude but the opposite polarity to that of the first voltage; measure a second parameter corresponding to one of (i) the time taken for current in the phase winding to exceed the threshold, and (ii) the magnitude of current in the phase winding at the end of the time interval; compare the first parameter and the second parameter; and determine that the rotor is in a first parked position if the first parameter is less than the second parameter, and that the rotor is in a second parked position if the first parameter is greater than the second parameter.

### BRIEF DESCRIPTION OF THE DRAWINGS

In order that the present invention may be more readily understood, embodiments of the invention will now be described, by way of example, with reference to the accompanying drawings, in which:

FIG. 1 is a schematic diagram of a permanent-magnet motor in accordance with the present invention;

FIG. 2 details the allowed states of an inverter in response to control signals issued by a controller of the permanent-magnet motor;

FIG. 3 illustrates a rotor of the permanent-magnet motor when parked in (a) a first position, and (b) a second position; and

FIG. 4 is a flow diagram of a method performed by the control system of the permanent-magnet motor in order to determine the parked position of the rotor.

### DETAILED DESCRIPTION OF THE INVENTION

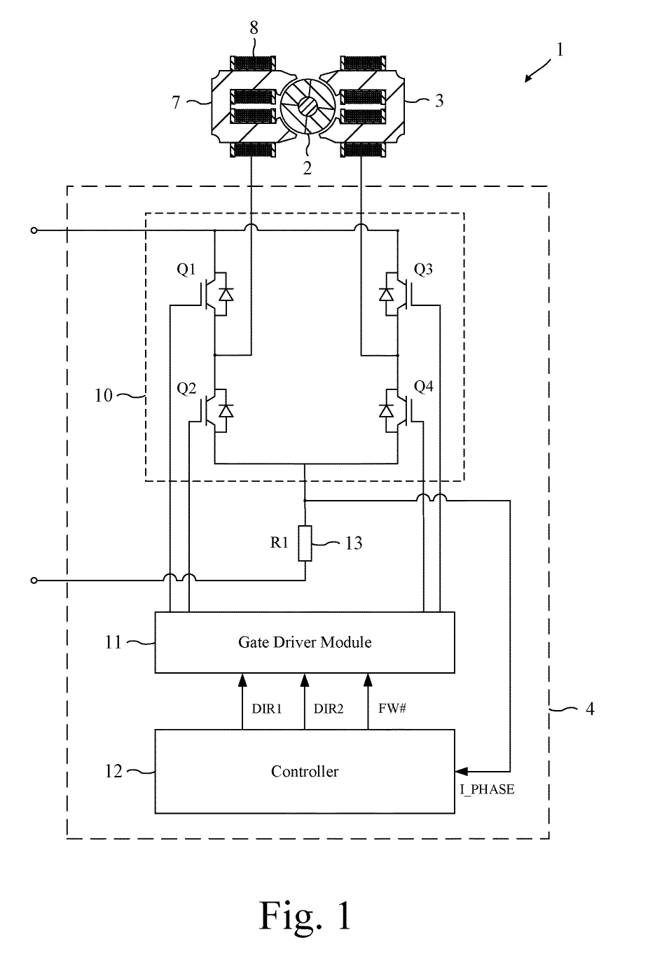

The permanent-magnet motor 1 of FIG. 1 comprises a rotor 2, a stator 3, and a control system 4.

The rotor 2 comprises a four-pole permanent magnet 5 secured to a shaft 6. The stator 3 comprises a pair of cores 7 having four salient poles, and a phase winding 8 wound about the cores 7.

The control system 4 comprises an inverter 10, a gate driver module 11, a controller 12, and a current sensor 13.

The inverter 10 comprises a full bridge of four power switches Q1-Q4 that couple the phase winding 8 to the voltage rails of a power supply (not shown).

The gate driver module 11 drives the opening and closing of the switches Q1-Q4 in response to control signals output by the controller 12.

The controller 12 is responsible for controlling the operation of the motor 1 and generates three control signals: DIR1, DIR2, and FW#. The control signals are output to the gate driver module 11, which in response drives the opening and closing of the switches Q1-Q4.

When DIR1 is pulled logically high and DIR2 is pulled logically low, the gate driver module 11 closes switches Q1 and Q4, and opens switches Q2 and Q3. As a result, a voltage having a first polarity is applied to the phase winding 8, causing current to be driven through the phase winding 8 from left to right. Conversely, when DIR2 is pulled logically high and DIR1 is pulled logically low, the gate driver module 11 closes switches Q2 and Q3, and opens switches Q1 and Q4. As a result, a voltage having a second, opposite polarity is applied to the phase winding 8, causing current to be driven through the phase winding 8 from right to left. DIR1 and DIR2 therefore control the polarity of the voltage that is applied to the phase winding 8 and thus the direction of current through the phase winding 8. If both DIR1 and DIR2 are pulled logically low, the gate drive module 11 opens all switches Q1-Q4.

When FW# is pulled logically low, the gate driver module 11 opens both high-side switches Q1,Q3. Current in the phase winding 8 then circulates or freewheels around the low-side loop of the inverter 10 in a direction defined by DIR1 and DIR2. Each switch Q1-Q4 conducts in a single direction only but includes a body diode. The current that freewheels around the low-side loop of the inverter 10 therefore flows through one of the low-side switches Q2,Q4 and through the body diode of the other low-side switch Q2,Q4. Certain types of power switch are capable of conducting in both directions when closed. In this instance, when FW# is pulled logically low, both low-side switches Q2,Q4 may be closed such that current flows through both of the switches Q2,Q4 rather than through one of the body diodes.

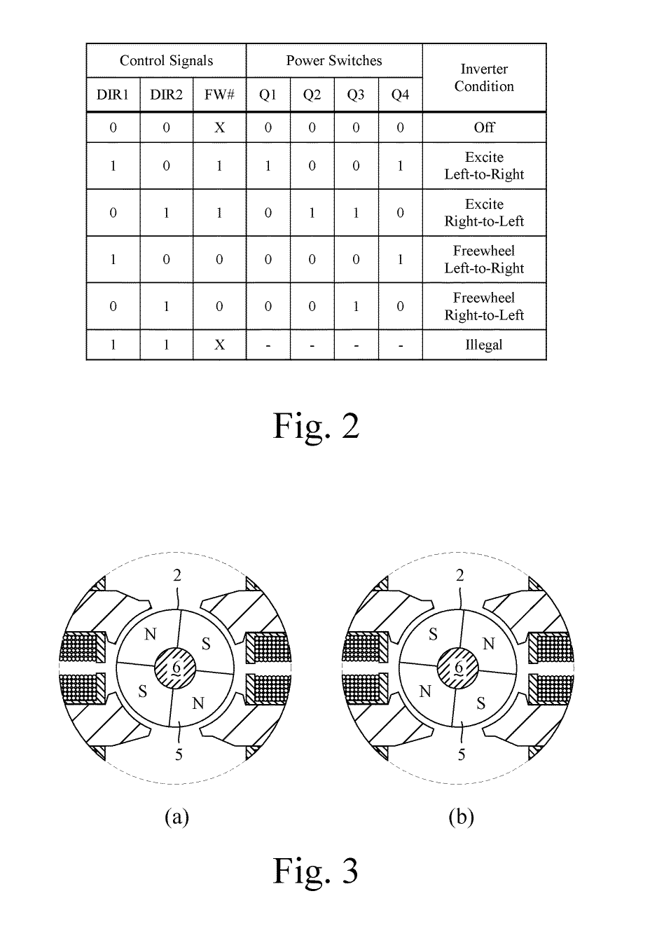

FIG. 2 summarises the allowed states of the switches Q1-Q4 in response to the control signals of the controller 12. Hereafter, the terms ‘set’ and ‘clear’ will be used to indicate that a signal has been pulled logically high and low respectively.

The current sensor 13 comprises a sense resistor R1 located between the inverter 10 and the zero voltage rail. The voltage across the current sensor 13 provides a measure of the current in the phase winding 8 when either DIR1 or DIR2 is set. The voltage across the current sensor 13 is output to the controller 12 as signal I_PHASE.

When the rotor 2 is stationary, the rotor 2 parks in one of four positions. However, owing to the rotational symmetry of the rotor 2, the rotor 2 may be said to park in one of two distinguishable positions. FIG. 3(a) illustrates the rotor 2 in a first parked position, and FIG. 3(b) illustrates the rotor 2 in a second parked position.

If the rotor 2 is parked in the first position and a positive voltage is applied to the phase winding 8, the resulting stator field will drive the rotor 2 in, say, a clockwise direction. If, however, the rotor 2 is parked in the second position and the same positive voltage is applied to the phase winding 8, the resulting stator field will drive the rotor in a counter-clockwise direction. The controller 12 therefore needs to know in which position the rotor 2 has parked in order to apply the appropriate polarity of voltage to the phase winding 8.

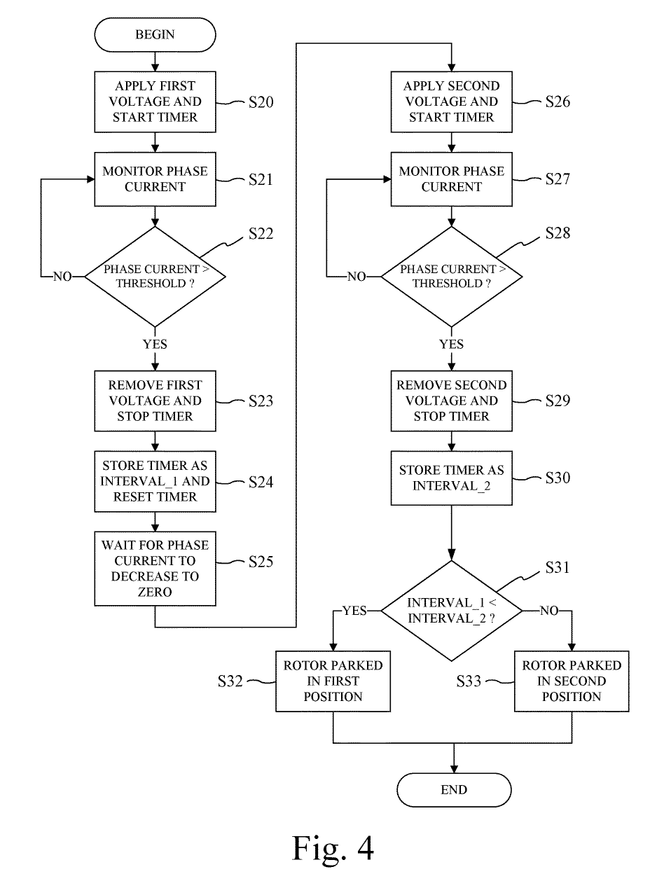

In order to determine the parked position of the rotor 2, the control system 4 performs the method outlined in FIG. 4. The controller 12 begins by setting DIR1, clearing DIR2 and setting FW#. At the same time, the controller 12 starts an internal timer (step S20). As a consequence of setting DIR1, a first voltage is applied to the phase winding 8. Current in the phase winding 8 therefore increases. The controller 12 monitors the magnitude of the phase current via the I_PHASE signal (step S21). When the phase current exceeds a threshold (step S22), the controller 12 clears FW# and stops the internal timer (step S23). The value of the internal timer corresponds to the time taken for the phase current to increase from zero to the threshold. The controller 12 stores the timer value as a first interval and resets the timer (step S24). As a consequence of clearing FW#, the first voltage is removed from the phase winding 8 and the phase current freewheels around the low-side loop of the inverter 10. The phase current 8 therefore decreases. The controller 12 then waits until the phase current has decreased to zero (step S25). The current sensor 13 is incapable of measuring the phase current during freewheeling. The controller 12 therefore waits a set period of time sufficient for the phase current to decrease to zero. The length of this period will naturally depend on the characteristics of the motor 1 (e.g. the inductance of the phase winding 8) as well as the magnitude of the threshold. At the end of the set period, the controller 12 clears DIR1, sets DIR2 and sets FW#. At the same time, the controller 12 restarts the timer (step S26). As a consequence of setting DIR2, a second voltage is applied to the phase winding 8. The second voltage has the same magnitude as the first voltage but the opposite polarity. Current in the phase winding 8 again increases and the controller 12 monitors the magnitude of the phase current via the I_PHASE signal (step S27). Although current in the phase winding 8 now flows in the opposite direction, the direction of current through the current sensor 13 is unchanged. The current sensor 13 is therefore sensitive to the magnitude of the phase current but not the polarity. When the phase current exceeds the threshold (step S28), the controller 12 clears FW# and stops the internal timer (step S29). The value of the timer again corresponds to the time taken for the phase current to increase from zero to the threshold. The controller 12 then stores this timer value as a second interval (step S30). Finally, the controller 12 compares the first interval and the second interval (step S31). If the first interval is less than the second interval, the controller 12 determines that the rotor 2 is in the first parked position (step S32). Otherwise, the controller 12 determines that the rotor 2 is in the second position (step S33).

When a voltage is applied to the phase winding 8, a stator field is generated. As the phase current increases, the density of the stator flux increases and eventually begins to saturate. As the stator 3 saturates, the inductance of the phase winding 8 decreases and thus the phase current increases at a faster rate. Depending on the polarity of the applied voltage and the parked position of the rotor 2, the rotor flux will either align with or oppose the stator flux. When the rotor flux is aligned with the stator flux, saturation of the stator 3 occurs more quickly. As a result, the phase current takes a shorter period of time to exceed the threshold. Conversely, when the rotor flux opposes the stator flux, saturation of the stator 3 occurs more slowly. As a result, the phase current takes a longer period of time to exceed the threshold. The controller 12 then makes use of this behaviour to determine the parked position of the rotor 2. In particular, the controller 12 arranges for a first voltage to be applied to the phase winding 8 by setting DIR1. The controller 12 then measures the time taken for the phase current to exceed the threshold and stores this as a first interval. The controller 12 then arranges for a second voltage of opposite polarity to be applied to the phase winding 8 by setting DIR2. The controller 12 then measures the time taken for the phase current to exceed the threshold and stores this as a second interval. By applying both a positive voltage and a negative voltage to the phase winding 8, the rotor flux will be aligned with the stator flux during one of the two intervals, and the rotor flux will oppose the stator flux during the other of the two intervals. The first interval will therefore be less than or greater than the second interval depending on the parked position of the rotor 2. For the purposes of the present discussion, the rotor flux is assumed to align with the stator flux when DIR1 is set and the rotor 2 is in the first parked position. Consequently, the first interval is less than the second interval when the rotor 2 is in the first parked position, and the first interval is greater than the second interval when the rotor 2 is in the second parked position.

In order to determine the parked position of the rotor 2, the controller 12 measures and compares two intervals. The first interval is measured when a voltage having a first polarity is applied to the phase winding 8, and the second interval is measured when a voltage having a second opposite polarity is applied to the phase winding 8. Conceivably, the controller 12 could measure a single interval by applying a voltage of just one polarity to the phase winding 8. The controller 12 could then compare the measured interval against a discriminating threshold. In particular, if the measured interval is less than the discriminating threshold (i.e. if the time taken for the phase current to exceed the threshold is relatively short), the controller 12 would determine that the rotor 2 is in the first parked position. Conversely, if the measured interval is greater than the discriminating threshold (i.e. if the time taken for the phase current to exceed the threshold is relatively long), the controller 12 would determine that the rotor 2 is in the second parked position. This alternative method has the advantage that the parked position of the rotor 2 may be determined more quickly. However, there are significant disadvantages associated with this method, as will now be explained. Tolerances in the motor 1, when mass produced, will result in a variance in the measured interval. As a result, the measured interval may be less than the discriminating threshold when it should be greater, or vice versa. The controller 12 would then incorrectly determine the parked position of the rotor 2. This is particularly true when the inductance of the phase winding 8 is relatively low and the phase current rises at a relatively fast rate irrespective of the parked position of the rotor 2. By measuring and comparing two intervals, the parked position of the rotor 2 may be determined more reliably. For example, if the inductance of the phase winding 8 for a particular motor were higher than normal, each measured interval would be longer. The use a single interval might then lead to an incorrect determination of the parked position. However, by using two intervals, the parked position would continue to be determined correctly. In particular, one interval would continue to be less than the other, irrespective of the change to each interval. A further problem with using a single measurement arises when the temperature of the rotor 2 changes. For example, the temperature of the rotor 2 may be significantly higher if the motor 1 has recently been used. As the temperature of the rotor 2 increases, the density of the rotor flux decreases. Consequently, when the rotor 2 is parked in a position in which the rotor flux aligns with the stator flux, saturation takes slightly longer and thus the measured interval is longer. Conversely, when the rotor 2 is parked in a position in which the rotor flux opposes the stator flux, the phase current rises at a slightly faster rate owing to the weaker rotor flux and thus the measured interval is shorter. There is therefore a temperature-dependent variance associated with each measured interval. As a result, when only one interval is measured, the interval may be less than the discriminating threshold when it should be greater, or vice versa. When two intervals are measured, the difference between the two intervals decreases as the temperature of the rotor 2 increases. However, one of the intervals continues to be less than the other. As a result, the parked position of the rotor 2 continues to be determined correctly. Measuring and comparing two intervals therefore has the distinct advantage that the parked position of the rotor 2 may be determined more reliably.

In the embodiment described above, the controller 12 measures the time taken for the phase current to exceed a threshold. In an alternative embodiment, the controller 12 may instead measure the magnitude of the phase current at the end of a specific time interval. As noted above, the rate at which the phase current rises depends on the parked position of the rotor 2. Consequently, when the rotor 2 is parked in a position in which the rotor flux aligns with the stator flux, the phase current will be higher at the end of the time interval. Conversely, when the rotor 2 is parked in a position in which the rotor flux opposes the stator flux, the phase current will be lower at the end of the time interval. Measuring the magnitude of the phase current at the end of the time interval may therefore be used to determine the parked position of the rotor 2. For the same reasons as those outlined above, the controller 12 measures the magnitude of the phase current at the end of the time interval after both a positive voltage and a negative voltage have been applied to the phase winding 8.

In a more general sense, the controller 12 may be said to measure a first parameter when the first voltage is applied to the phase winding 8, and a second parameter when the second voltage is applied to the phase winding 8. Each parameter then corresponds to either (i) the time taken for the phase current to exceed a threshold, or (ii) the magnitude of the phase current at the end of a time interval. The controller 12 then compares the first parameter and the second parameter and determines the parked position of the rotor 2 in response to the comparison.

Although the parked position of the rotor 2 may be determined by measuring the magnitude of the phase current at the end of a time interval, this method has the disadvantage that the phase current is less well controlled. For example, during the time interval, the phase current might increase to an excessive level that might damage components of the control system 4. This may be mitigated by selecting an appropriate length of time interval and/or through the use of a fail-safe threshold. However, the former method of measuring the time taken for the phase current to exceed a threshold has the advantage that the magnitude of the phase current is limited by the threshold.

In the embodiment described above, the first voltage is removed from the phase winding 8 by clearing FW#. As a result, the high-side switches Q1,Q3 are opened and current in the phase winding 8 freewheels around the low-side loop of the inverter 10. Conceivably, the low-side switches Q2,Q4 may instead be opened such that current freewheels around the high-side loop of the inverter 10. Depending on the inductance of the phase winding 8, the phase current may take a relatively long time to decrease to zero during freewheeling. Accordingly, rather than freewheeling, the first voltage may be removed from the phase winding 8 by opening all of the switches Q1-Q4 of the inverter 10. Current in the phase winding 8 would then be returned to the power supply via the body diodes and thus the phase current would decrease at a faster rate. In a further alternative, removing the first voltage may involve applying the second voltage to the phase winding 8. Since the second voltage has the opposite polarity to that of the first voltage, the phase current would be pulled more rapidly down to zero.

The current sensor 13 comprises a single sense resistor R1. The use of a single resistor has the advantage of reducing the component cost of the control system 4. However, a disadvantage is that the current sensor 13 is incapable of measuring the phase current after the first voltage has been removed from the phase winding 8. Consequently, after measuring the first parameter, the controller 12 waits a set period of time sufficient for the phase current to decrease to zero before applying the second voltage to the phase winding 8. Conceivably, the current sensor 13 may comprise means capable of additionally measuring the phase current when the first voltage is removed. For example, the current sensor 13 may comprise a pair of resistors, each of which is located on a lower leg of the inverter 10. One of the resistors would then provide a measure of the current when flowing through the phase winding 8 from left to right, and the other resistor would provide a measure of the current when flowing through the phase winding 8 from right to left. As a further alternative, the current sensor 13 may comprise a current transformer or other transducer that is capable of sensing the current in the phase winding 8. Where the current sensor 13 is capable of measuring the phase current after the first voltage has been removed, the controller 12 may monitor the magnitude of the phase current after measuring the first parameter, and apply the second voltage when the measured phase current reaches zero.

Although reference has thus far been made to a motor 1 having four rotor poles, four stator poles, and a single phase winding 8, the method employed by the control system 4 might equally be used to determine the parked position of a motor having fewer or greater poles and/or additional phase windings.

1. A method of determining the parked position of a rotor of a permanent-magnet motor, the method comprising:
applying a first voltage to a phase winding of the motor;
measuring a first parameter corresponding to one of (i) the time taken for current in the phase winding to exceed a threshold, and (ii) the magnitude of current in the phase winding at the end of a time interval;
removing the first voltage from the phase winding;
waiting for current in the phase winding to decrease to zero;
applying a second voltage to the phase winding of the motor, the second voltage having the same magnitude but the opposite polarity to that of the first voltage;
measuring a second parameter corresponding to one of (i) the time taken for current in the phase winding to exceed the threshold, and (ii) the magnitude of current in the phase winding at the end of the time interval;
comparing the first parameter and the second parameter; and
determining that the rotor is in a first parked position if the first parameter is less than the second parameter, and that the rotor is in a second parked position if the first parameter is greater than the second parameter.

2. A permanent-magnet motor comprising a rotor, a stator and a control system configured to perform a method comprising:
applying a first voltage to a phase winding of the motor;
measuring a first parameter corresponding to one of (i) the time taken for current in the phase winding to exceed a threshold, and (ii) the magnitude of current in the phase winding at the end of a time interval;
removing the first voltage from the phase winding;
waiting for current in the phase winding to decrease to zero;
applying a second voltage to the phase winding of the motor, the second voltage having the same magnitude but the opposite polarity to that of the first voltage;
measuring a second parameter corresponding to one of (i) the time taken for current in the phase winding to exceed the threshold, and (ii) the magnitude of current in the phase winding at the end of the time interval;
comparing the first parameter and the second parameter; and
determining that the rotor is in a first parked position if the first parameter is less than the second parameter, and that the rotor is in a second parked position if the first parameter is greater than the second parameter.

3. The permanent-magnet motor of claim 2, wherein the control system comprises an inverter, a gate driver module, a controller, and a current sensor, the inverter is coupled to the phase winding, the gate driver module drives the opening and closing of switches of the inverter in response to control signals output by the controller, the current sensor outputs a signal that provides a measure of the current in the phase winding, and the controller outputs a first set of control signals such that the first voltage is applied to the phase winding, measures the first parameter using the signal output by the current sensor, outputs a second set of control signals such that the first voltage is removed from the phase winding, outputs a third set of control signals such that the second voltage is applied to the phase winding, measures the second parameter using the signal output by the current sensor, compares the first parameter and the second parameter, and determines that the rotor is in a first parked position if the first parameter is less than the second parameter and that the rotor is in a second parked position if the first parameter is greater than the second parameter.

4. A control system for determining the parked position of a rotor of a permanent-magnet motor, the control system comprising:
means for applying a first voltage to a phase winding of the motor;
means for measuring a first parameter corresponding to one of (i) the time taken for current in the phase winding to exceed a threshold, and (ii) the magnitude of current in the phase winding at the end of a time interval;
means for removing the first voltage from the phase winding;
means for waiting for current in the phase winding to decrease to zero;
means for applying a second voltage to the phase winding of the motor, the second voltage having the same magnitude but the opposite polarity to that of the first voltage;
means for measuring a second parameter corresponding to one of (i) the time taken for current in the phase winding to exceed the threshold, and (ii) the magnitude of current in the phase winding at the end of the time interval;
means for comparing the first parameter and the second parameter; and
means for determining that the rotor is in a first parked position if the first parameter is less than the second parameter, and that the rotor is in a second parked position if the first parameter is greater than the second parameter.

5. A control system for determining the parked position of a rotor of a permanent-magnet motor, the control system comprising one or more processors, memory, and one or more programs, wherein the one or more programs are stored in the memory and configured to be executed by the one or more processors, the one or more programs including instructions that when executed by the one or more processors, cause the control system to:
apply a first voltage to a phase winding of the motor;
measure a first parameter corresponding to one of (i) the time taken for current in the phase winding to exceed a threshold, and (ii) the magnitude of current in the phase winding at the end of a time interval;
remove the first voltage from the phase winding;
wait for current in the phase winding to decrease to zero;
apply a second voltage to the phase winding of the motor, the second voltage having the same magnitude but the opposite polarity to that of the first voltage;
measure a second parameter corresponding to one of (i) the time taken for current in the phase winding to exceed the threshold, and (ii) the magnitude of current in the phase winding at the end of the time interval;
compare the first parameter and the second parameter; and
determine that the rotor is in a first parked position if the first parameter is less than the second parameter, and that the rotor is in a second parked position if the first parameter is greater than the second parameter.
